(19) United States
(12) Patent Application Publication
(10) Pub. No.: US 2025/0283926 A1
(43) Pub. Date: Sep. 11, 2025

(54) METHOD AND DEVICE FOR MEASURING AN EARTH RESISTANCE IN A BATTERY CHARGING SYSTEM

(71) Applicants: ELDOR CORPORATION S.P.A., Orsenigo (Como) (IT); DR. ING. H.C. F. PORSCHE AG, Stuttgart (DE)

(72) Inventors: Francesco BERTINO, Orsenigo (Como) (IT); Pasquale FORTE, Orsenigo (Como) (IT); Paolo LISANTI, Orsenigo (Como) (IT)

(21) Appl. No.: 18/861,157

(22) PCT Filed: Apr. 27, 2023
(86) PCT No.: PCT/IB2023/054357

§ 371 Date: Oct. 28, 2024

(30) Foreign Application Priority Data
Apr. 29, 2022 (IT) 102022000008597

(51) Int. Cl. G01R 27/18; B60L 53/60; H02J 7/00

(52) U.S. Cl. CPC G01R 27/18; H02J 7/0029; H02J 7/0047; B60L 53/60

(57) ABSTRACT

A method for measuring an earth resistance in a battery charging system connected to the power grid includes, for each measurement cycle, injecting a first, alternating current, signal between a first, neutral node and a second, earth node, detecting a first voltage signal representing an electrical potential difference between the first and second node, calculating an earth resistance value as a function of the first voltage signal. Further, injecting between the first, neutral node and the second, earth node an information signal representing the calculated earth resistance value. Before the injecting the first alternating current signal: detecting one or more information signals generated by further battery charging systems connected to the power grid; determining the earth resistance value based on the information content of the received information signals; proceeding with steps a) to c) if a number of information signals lower than the pre-set limit value is detected.

This invention relates to a method and device for measuring an earth resistance in a battery charging system, preferably traction (automotive) batteries.

The main application of this invention is in the automotive field, in particular in the design and manufacture of charging systems for electric batteries.

In the context of electric vehicles, in fact, the battery pack charging mode is divided into two distinct relative macro-categories: on-vehicle chargers and ground chargers.

On-board chargers are, as their name suggests, integrated into the vehicle and include all the power and control electronics needed to convert the alternating current from the grid into the direct current needed to charge the battery pack.

On the other hand, ‘ground’ chargers are the well known ‘columns’ or wallboxes that directly perform the conversion by supplying the vehicle with direct current.

It is therefore clear that battery chargers of both categories, having to manage an alternating current coming from the grid and having to convert it into direct current for charging high-voltage batteries, present considerable criticalities in terms of user safety, as they must be equipped with appropriate protection systems.

One of the main areas of research relating to safety systems is that of verifying that the vehicle or column is correctly ‘earthed’, an operation that in some cases is carried out by injecting a current signal into the grid, measuring the resulting voltage by means of appropriate computational calculations, and calculating the relevant earth resistance.

However, this procedure is not without its drawbacks, as its effectiveness is closely linked to the boundary conditions, i.e. the noisiness of the grid.

Considering that the distribution network has a large number of users with the most varied applications connected to the same substation, it is not rare that the frequency used in the generation of the current signal is already occupied by very significant disturbances.

This, considering the stringent regulatory constraints that limit the current intensity that can be used for measurement to little more than 1 mA, entails in several cases a real difficulty in determining which component of the voltage signal detected is to be correlated with the injected signal and which is instead the noise component.

It must also be considered that the amount and type of loads that are connected to the grid is not to be considered a constant parameter, but varies over time, even significantly, which led the Applicant to study a possible solution that would make the system robust to these variables.

It is therefore the purpose of this invention to provide a method for measuring an earth resistance in a battery charging system that is able to overcome the above-mentioned drawbacks of the prior art.

In particular, the purpose of this invention is to provide a method and device for measuring an earth resistance in a battery charging system that maintains its efficiency regardless of the type and number of loads connected to the grid.

Said purposes are achieved with a method and a device for measuring an earth resistance in a battery charging system that has the characteristics of one or more of the following claims.

In particular, the method comprises, for each measurement cycle, injecting a first alternating current signal between a first neutral node and a second earth node.

The first current signal has a pre-set duration and a predetermined injection frequency.

A first voltage signal representing an electrical potential difference between said first and second node is then detected.

At this point, a value of an earth resistance as a function of said first voltage signal is calculated.

According to the invention, the method also involves a step of injecting between said first neutral node and said second earth node an information signal representing said calculated earth resistance value.

Preferably, moreover, prior to said step of injecting the first alternating current signal, one or more information signals generated by further battery charging systems connected to said power grid are detected (from the grid).

Preferably, if information signals in a number at least equal to a pre-set limit value are detected, the value of the earth resistance is determined on the basis of the information content of said information signals received.

Alternatively, if information signals are detected in a number lower than said pre-set limit value, the method provides for calculating the value of the earth resistance by implementing the steps of injecting the first current signal and detection of the first voltage signal described above, with subsequent injection of the information signal into the grid.

According to a further, optional aspect of the invention, there is a step for inhibiting the injection of said first alternating current signal if information signals are detected in a number at least equal to a pre-set limit value.

Another purpose of this invention is to provide a device for measuring an earth resistance for an on-board charger, which is preferably configured to implement the method described above.

The dependent claims, incorporated herein by reference, correspond to different embodiments of the invention.

Further features and advantages of this invention will become clearer from the indicative, and therefore non-limiting, description of a preferred, but not exclusive, embodiment of a method and device for measuring an earth resistance in a battery charging system, as illustrated in the accompanying drawings wherein:

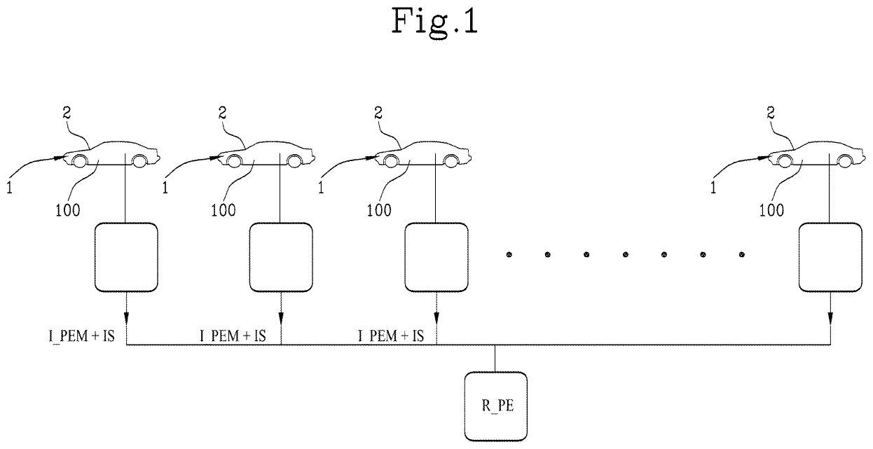

FIG. 1 schematically shows an electric vehicle battery charging facility in which the method of this invention is implemented.

With reference to the appended FIGURES, the numerical reference 100 generically identifies a facility for charging electric vehicle batteries, to which battery charging systems equipped with a device for measuring an earth resistance according to this invention can be connected.

Purely by way of example, a method and a device within an on-board charger device will be described below, without, however, this description being intended to define a limitation to the application and scope of the invention.

A similar description could be provided for ground charging systems, such as, for example, columns or wall-boxes, but since the measurement of the earth resistance is a more critical parameter within vehicles, we preferred, in the following, to provide a description of the application in which the invention has greater advantages.

It should be noted that the expression on-board charger device is intended in this text to define, in a generic manner, any charging system for a traction battery pack capable of connecting to the alternating current power grid and converting it to direct current before supplying power to the battery.

For this reason, the battery charger comprises at least one casing (earthed) connected to a power grid connection socket and containing a converter unit configured to convert the alternating current from the mains into a direct current useful for charging the battery pack.

The connection socket is thus configured to receive phases and/or neutral.

The method 1 for measuring the earth resistance that is the subject of the invention involves injecting (i.e. generating) an alternating current signal between a first neutral node and a second earth node.

The measurement signal is preferably generated by means of a current generator.

Note that the neutral node may alternatively be:
a physical node in the grid (i.e. a node directly connected to the neutral of the connection socket);
a reconstructed virtual node with potential corresponding to the earth potential and in electrical continuity with the phases.

Preferably, a grid noise analysis is also performed prior to the generation or injection of the phase measurement signal.

This grid noise analysis step involves detecting a reference signal representing the grid voltage and identifying a free frequency range in which said voltage signal has a minimum or zero value (e.g. minimum or zero amplitude).

More precisely, a spectral analysis of said reference signal is performed and a pre-set injection frequency of the first current signal is identified as the frequency with the lowest spectral content.

In the preferred embodiment, the spectral analysis is not performed on the entire frequency spectrum, but only on, alternatively, a first, low-frequency range or a second, high-frequency range.

Advantageously, this speeds up and optimises the analysis.

Preferably, at the start of the method, i.e. at the connection of the battery charging device with the grid, the pre-set frequency is selected within the second, high-frequency range.

It should be noted that, preferably, the first, low-frequency range is between 0 Hz and 200 Hz, more preferably between 5 Hz and 150 Hz.

The second, high frequency range, is preferably between 200 Hz and 600 Hz, more preferably between 250 Hz and 400 Hz.

The method thus involves detecting a first voltage signal representing an electrical potential difference between said first and second node and calculating an earth resistance value as a function of said first voltage signal.

These steps are of themselves known, already patented by the Applicant under Italian patent application 102020000031625, incorporated herein for reference.

For this reason, the phases for measuring the earth resistance R_PE will not be described further.

According to the invention, it comprises a step of injecting between said first neutral node and said second earth node an information signal IS representing said calculated earth resistance value R_PE.

In other words, according to the invention the method involves exploiting the potential difference between neutral and earth to inject a further signal to earth that can be read by other devices connected to the grid.

Preferably, the information signal is a highly recognisable signal. A possible frequency range for said signal is preferably between 600 hz and 5 khz.

The amplitude of said information signal is preferably between 100 and 500 mV.

In this respect, the method preferably involves analysing the grid (actively or passively) prior to said first alternating current signal injection phase.

More specifically, preferably the method provides for detecting one or more information signals IS generated by additional battery charging systems connected to said power grid.

Advantageously, this makes it possible to detect whether other charging systems have detected the earth resistance.

If information signals IS are detected in a number at least equal to a pre-set limit value, the earth resistance value R_PE is determined on the basis of the information content of said information signals IS received.

Alternatively, if fewer information signals IS are detected than said pre-set limit value, the earth resistance value is determined by means of the steps described above (injection of the first current signal, detection of the first voltage signal, calculation of the earth resistance and injection of the information signal).

Preferably, a step of inhibiting the injection of said first signal in alternating current I_PEM is provided in case information signals IS are detected in a number at least equal to a pre-set limit value.

In the preferred embodiment, the pre-set limit value is between 2 and 10.

It should be noted that, preferably, there is a network noise analysis step within a selected frequency range prior to said injection of the first alternating current signal I_PEM.

The noise analysis step involves taking a reference signal representing the mains voltage, performing a spectral analysis of said reference signal and identifying the injection frequency as the frequency with the lowest spectral content.

Advantageously, in this way, all devices connected to the grid will proceed to inject a current signal into the grid at a different frequency, thus avoiding creating disturbances in each other's measurements.

For a limited number of battery charging devices, therefore, below the limit value, the earth resistance measurement will be performed independently for each vehicle by injecting first alternating current signals at different frequencies.

For a large number of battery charging devices connected to the grid, even significantly above the limit value, the measurement will instead be carried out using those already taken by the devices described above, avoiding crowding the frequency band with independent signals used to measure the same quantity.

Preferably, the step of inhibiting the injection of said first signal in alternating current I_PEM is only performed if the earth resistance values calculated by the additional charging systems fall within a pre-set tolerance range.

Advantageously, this makes the system robust to disturbances, as it allows the individual device to proceed with independent measurement if one or more of the measured resistances fall outside the tolerance range.

In a preferred embodiment, the information signal IS has a first contribution, representing said earth resistance value R_PE, and a second contribution, representing the state of the battery charger 100.

The information signal IS may thus be a single signal containing a double information contribution or equivalently defined by a pair of signals travelling on different channels.

“Status of the battery charger 100” means, in this text, the charging, discharging (vehicle to grid) or switching-off (vehicle charged) condition of the battery charger.

Preferably, the method involves being able to inhibit the injection of said first alternating current signal depending on both said first and said second contribution of the information signals IS generated by the additional charging systems connected to the grid.

Advantageously, it is thus possible to stop the injection by a battery charger that is already charged, by imparting the activation of the generation of the first signal to an additional charger to which this functionality was previously inhibited, preferably following a master-slave logic.

Another purpose of this invention is to provide a device for measuring an earth resistance for a battery charger 100, wherein said battery charger device comprises a power grid connection socket G and a converter assembly configured to convert alternating current from the power grid into a direct current that can be used to charge a battery pack.

The measurement device comprises a current generator with variable amplitude and frequency configured to generate and inject into the power grid, between a first, neutral node and a second, earth node PE an alternating current measurement signal corresponding to the first current signal I_PEM.

A voltage detection module configured to detect a voltage signal representing the potential difference between the first N and the second PE node is also provided.

A processing module 2 is also connected to the generator and the detection module and configured to implement the method that is the subject of the invention.

In particular, the processing module 2 is configured to:
a) activate said current generator so as to inject the measurement signal in alternating current between the first neutral N node and the second earth PE node;
b) receive from the detection module a voltage signal in response to said injection of the measurement signal;
c) calculate an earth resistance value as a function of said voltage signal.

According to the invention, the processing module 2 (or another component connected to it) is configured to inject between said first neutral node and said second earth node an information signal representing said earth resistance value R PE calculated.

Preferably, moreover, the processing module 2 is configured to perform the following steps
detecting, prior to said current generator activation, one or more information signals IS generated by additional battery charging systems connected to said power grid G;
counting a number of information signals IS detected;
comparing said number of information signals IS detected with a pre-set limit value; and:
   determining the earth resistance R_PE value on the basis of the information content of said information signals IS received, when the number of information signals IS detected is equal to said pre-set limit value;
   proceeding with steps a) to c) and with the injection of the information signal if fewer information signals IS are detected than said pre-set limit value.

Preferably, moreover, similarly to the method, the processing module 2 is configured to inhibit said activation of the current generator when the number of information signals detected is equal to said prefixed limit value.

The invention achieves its intended purposes and entails important advantages.

Indeed, the use of a method of disabling the “active” measurement of the earth resistance as the number of devices connected to the grid increases means the efficiency and accuracy of the measurement are independent of the number of vehicles being recharged.

1. A method for measuring an earth resistance in a battery charging system connected to a power grid; said method comprising, for each measurement cycle, the steps of:
a) injecting a first, alternating current, signal between a first, neutral node and a second, earth node; said first current signal having a pre-set duration and a pre-set injection frequency;
b) detecting a first voltage signal representing an electrical potential difference between said first and said second node;
c) calculating an earth resistance value as a function of said first voltage signal;
characterised in that it comprises a step of
d) injecting between said first, neutral node and said second, earth node an information signal representing said calculated earth resistance value, wherein, before said step of injecting the first alternating current signal, the following steps are provided:
detecting one or more information signals generated by further battery charging systems connected to said electrical network;
determining the earth resistance value based on the information content of said received information signals if the number of information signals detected is at least equal to a pre-set limit value;
proceeding with steps a) to d) when the number of information signals detected is less than said pre-set limit value.

2. The method according to claim 1, comprising a step of inhibiting the injection of said first, alternating current, signal when the number of information signals detected is at least equal to a pre-set limit value.

3. The method according to claim 1, comprising a step of analysing the grid noise within a frequency range selected prior to said injection of the first, alternating current signal; said step of analysing the noise provide for:
detecting a reference signal representative of the grid voltage;
performing a spectral analysis of said reference signal;
identifying the injection frequency as the frequency with the lowest spectral content.

4. The method according to claim 1, wherein the step of inhibiting the injection of said first, alternating current, signal is only performed when the earth resistance values calculated by the further charging systems fall within a predetermined tolerance interval.

5. The method according to claim 1, wherein the information signal presents a first contribution, representing said earth resistance value, and a second contribution, representing the state of the battery charging device; said step of inhibiting the injection of said first, alternating current, signal being carried out as a function of both said first and said second contributions of the information signals generated by the further charging systems connected to the network.

6. A device for measuring an earth resistance for a battery charging device, wherein said battery charging device comprises a socket for connection to the power grid and a converter assembly (not shown) configured to convert the alternating current coming from the power grid into a direct current that can be used for recharging a battery pack; said measuring device comprising:
a current generator with variable amplitude and frequency configured to generate and inject an alternating current measurement signal into the power grid between a first, neutral node and a second, earth node;
a voltage detection module configured to detect a voltage signal representing the potential difference between the first and the second node;
a processing module configured to:
a) activate said current generator so as to inject the alternating current measurement signal between the first, neutral node and the second, earth node;
b) receive a voltage signal from the detection module in response to said measurement signal injection;
c) calculate an earth resistance value as a function of said voltage signal; characterised in that said processing module is configured to inject between said first, neutral node and said second, earth node an information signal representing said calculated earth resistance value;
wherein the processing module is configured to perform the following steps:
detecting, prior to said activation of the current generator, one or more information signals generated by further battery charging systems connected to said power grid;
counting a number of information signals detected;
comparing said number of information signals detected with a pre-set limit value and:
determining the earth resistance value based on the information content of said received information signals when the number of information signals detected is equal to said pre-set limit value;
proceeding with steps a) to c) when the number of information signals detected is less than said pre-set limit value.

7. The device according to claim 6, wherein the processing module is configured to inhibit said activation of the current generator when the number of information signals detected is equal to said pre-set limit value.
